(19) United States
(12) Patent Application Publication
(10) Pub. No.: US 2013/0087903 A1
(43) Pub. Date: Apr. 11, 2013

(54) Electronics Packaging For High Temperature Downhole Applications

(71) Applicant: SCHLUMBERGER TECHNOLOGY CORPORATION, Sugar Land, TX (US)

(72) Inventors: Mohamed Salim Cherchali, Chatillon (FR); Bernard Parmentier, Maurepas (FR); Sandrine J. Lelong-Feneyrou, Igny (FR); Vincent Martinez-Llorca, Courbevoie (FR); Francois Barbara, Sartrouville (FR)

(73) Assignee: SCHLUMBERGER TECHNOLOGY CORPORATION, Sugar Land, TX (US)

(21) Appl. No.: 13/627,935

(22) Filed: Sep. 26, 2012

Related U.S. Application Data
(60) Provisional application No. 61/544,178, filed on Oct. 6, 2011.

(51) Int. Cl. H01L 23/488; H01L 21/56

(52) U.S. Cl. 257/690; 438/127; 257/E23.023; 257/E21.502

(57) ABSTRACT

A downhole tool is described. The downhole tool includes a work device and an electronics packaging connected to the work device. The electronics packaging comprises a housing, a substrate, at least one first type component, and at least one second type component. The housing defines a void. The substrate is positioned within the void of the housing and forms a first cavity and a second cavity relative to the housing. The first cavity and the second cavity are isolated to form separate atmospheric chambers. The at least one first type component is disposed in the first cavity and connected to the substrate. The at least one second type component is disposed in the second cavity and connected to the substrate. The at least one first type component is different from the at least one second type component.

### CROSS-REFERENCE TO RELATED APPLICATIONS

The present patent application claims priority under 35 U.S.C. §119 to the provisional patent application identified by U.S. Ser. No. 61/544,178 filed on Oct. 6, 2011, the entire content of which is hereby incorporated herein by reference.

### TECHNICAL FIELD

The present invention relates generally to methods and apparatus for controlling the operation of downhole well tools from the surface, and particularly to a new and improved electronics packaging system for a downhole tool control system adapted for operation in harsh environments, involving high pressure and high temperature, such as those experienced by equipment in a downhole environment.

### BACKGROUND ART

It has become commercially prudent to perform well service operations, such as formation testing and evaluation, in very deep wells using pressure controlled valve devices such as those taught by Upchurch, U.S. Pat. No. 4,796,699, which is hereby incorporated by reference.

Pressure controlled valve devices are valve structures that are operably responsive to command signals such as those from pressure pulses applied from surface to the fluid in the annulus, or from other wireless signals sent downhole such as acoustic signals or electromagnetic signals. Downhole electronics within the downhole tool must decode the incoming signals and provide the electrical stimulus to operate the tool in accordance with the received command.

In Upchurch, for example, a well testing tool is disclosed which is not totally mechanical in nature, and embodies a microelectronics package and a set of solenoids responsive to the microelectronics package for opening and/or closing a valve disposed in the tool. As such, the well testing tool of Upchurch is susceptible to damage in extreme, harsh conditions.

Recently, the search for hydrocarbons is leading to deeper wells having ever more extreme conditions related to, among other things, downhole pressure and temperature. While the electronics contained within the various downhole devices are typically protected from extreme pressure by being sealed within an atmospheric chamber. However, even when separated certain downhole environmental factors while sealed in an atmospheric chamber, the electronics are nevertheless exposed to the downhole temperatures.

Currently, conventional electronics are limited in operation to approximately 150° C./160° C. Traditionally, electronics are mounted on a Printed Circuit Board (PCB), which has a limited lifetime in a high-temperature (HT) environment (above 150° C.). Electronic components that may be available, which work at temperatures above approximately 150° C./160° C. generally fall into three major categories: (1) legacy ceramic components developed mostly for the military market that work at high temperature, (2) multi-chip modules (MCM) developed (or that can be developed) by end users and others using die known to work at high temperatures, and (3) a few very basic and very expensive silicon-on-insulator (SOI) components developed specifically for the market. A MCM may contain multiple integrated circuits, semiconductor dies, or other discrete components packaged onto a unifying substrate. Packaging multiple integrated circuits, semiconductor dies, or other components onto a unifying substrate may allow for the use of those circuits, dies, or components as a single component. For added reliability at high temperatures, it is preferable that all system electronics be comprised primarily of hermetically sealed MCMs. These MCMs will serve to eliminate or at least minimize interconnections between integrated circuits and circuit boards, an inherent weakness in high temperature applications.

To operate at substantially higher temperatures it is often necessary to create a special package using ceramic substrate technologies, to create a MCM, in which individual semiconductor component dies or integrated circuits, preferably without any individual plastic packaging, are placed on a ceramic substrate, the substrate serving as the conducting pathways analogous to a PCB in conventional electronics. Packaging integrated circuits within a MCM often employs a monolithic structure to interconnect two or more chips. The signal and electrical pads of the die are joined to their corresponding conducting pads on the ceramic substrate by methods such as aluminum wire bonding as is well known in the art. The many semiconductor dies are then usually surrounded by walls made from a material, such as Kovar, which are brazed to traces on the ceramic substrate to form a surrounding rectangular box. A lid, also made of a material, such as Kovar, is then placed over the four walls. The air is then evacuated from the interior of the box while simultaneously injecting an inert gas, such as nitrogen, into the interior of the box before brazing the seams of the lid in place to form a hermetically sealed enclosure for the semiconductor die.

As is well known in the art, this MCM assembly eliminates the need for packaging materials such as plastic to surround and hermetically seal each semiconductor die from the damaging effects of atmospheric corrosion and chemical reaction. Also eliminated is the repeated expansion and contradiction caused by extreme temperature acting on conventionally packaged semiconductors, where typical plastic packaging materials often possess thermal expansion coefficients that are significantly different than the encapsulated semiconductor die. This thermal mismatch of material properties can lead to a failure in the hermetic seal between the conventional package and the semiconductor die, leading to eventual failure in the operation of the semi-conductor component.

In addition to active digital semi-conductor components, very often passive devices such as resistors, capacitors, inductors, etc. are needed to form a complete functioning circuit. These passive components often require a different connection technology than do semiconductor dies. An example is soldering of gold plated contacts for passive components versus aluminum wire-bonding of active semiconductor dies. The different attachment and bonding technologies used on active versus passive components can be a source of adverse physical or chemical reactions which can lead to reliability problems over time. For example out-gassing of trace chemicals from one process could adversely affect components using another process. The potential for this type of subtle chemical or physical reaction increases as the temperature increases, and therefore the available activation energy, such as is the case in more extreme downhole conditions.

Therefore, a need exists to maintain high reliability of electronic circuits in downhole tools destined for use in extreme high temperature environments and to avoid the potential for mixing component types which require different and incompatible bonding or attachment technologies within the same sealed enclosure.

It is therefore desirable to provide a well tool control system and method for performing well service operations in harsh conditions, such as high pressure and high temperature.

### BRIEF DESCRIPTION OF THE DRAWINGS

Certain embodiments of the present invention will hereafter be described with reference to the accompanying drawings, wherein like reference numerals denote like elements, and:

FIG. 1 shows a schematic view of an exemplary testing or production installation;

FIG. 2 shows a block diagram of an exemplary downhole tool constructed in accordance with the present disclosure;

FIG. 3 shows a cross-sectional diagram of an exemplary electronics package constructed in accordance with the present disclosure;

FIG. 4 shows an exploded view of the electronics package;

FIG. 5 shows a fragmental view of a substrate according to the present disclosure; and

FIG. 6 shows another fragmental view of the substrate according to the present disclosure.

### DETAILED DESCRIPTION

Specific embodiments of the present disclosure will be described in detail with reference to the accompanying drawings. Further, in the following detailed description of embodiments of the present disclosure, numerous specific details are set forth in order to provide a more thorough understanding of the invention. However, it will be apparent to one of ordinary skill in the art that the embodiments disclosed herein may be practiced without these specific details. In other instances, well-known features have not been described in detail to avoid unnecessarily complicating the description.

The terminology and phraseology used herein is solely used for descriptive purposes and should not be construed as limiting in scope. Language such as “including,” “comprising,” “having,” “containing,” or “involving,” and variations thereof, is intended to be broad and encompass the subject matter listed thereafter, equivalents, and additional subject matter not recited.

Moreover, in this description the terms “up” and “down”; “upward” and downward”; “upstream” and “downstream”; and other like terms indicating relative positions above or below a given point or element are used in this description to more clearly described some embodiments of the invention. However, when applied to apparatus and methods for use in wells that are deviated or horizontal, such terms may refer to a left to right, right to left, or other relationship as appropriate.

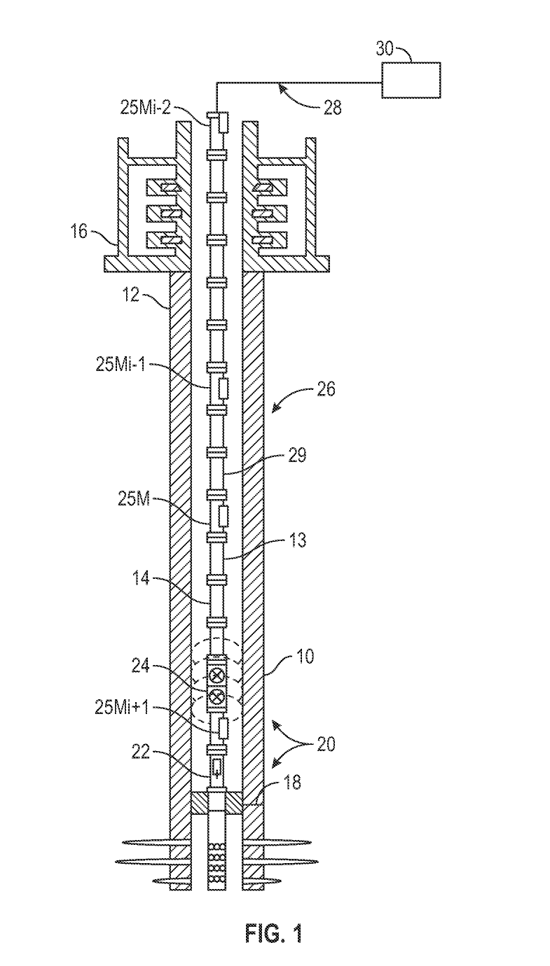

The present invention is particularly applicable to testing and/or production installations such as are used in oil and gas wells or the like. FIG. 1 shows a schematic view of such a system. Once a well 10 has been drilled through a formation, the well 10 can be used to perform tests, and determine various properties of the formation through which the well has been drilled. In the example of FIG. 1, the well 10 has been lined with a steel casing 12 (cased hole) in the conventional manner, although similar systems can be used in unlined (open hole) environments. In order to test the formations, it is preferable to place testing apparatus in the well close to the regions to be tested, to be able to isolate sections or intervals of the well, and to convey fluids from the regions of interest to the surface. This is commonly done using a jointed tubular drill pipe, drill string, production tubing, sections thereof, or the like (collectively, tubing 14) which extends from well-head equipment 16 at the surface down inside the well 10 to a zone of interest. The well-head equipment 16 can include blow-out preventers and connections for fluid, power and data communication.

A packer 18 is positioned on the tubing 14 and can be actuated to seal the borehole around the tubing 14 at the region of interest. Various pieces of downhole test equipment (collectively, downhole tool(s) 20) are connected to the tubing 14 above or below the packer 18. Such downhole tool(s) 20 may be referred to herein as one or more downhole equipment and may include, but is not limited to: additional packers; tester valves; circulation valves; downhole chokes; firing heads; TCP (tubing conveyed perforator) gun drop subs; samplers; pressure gauges; downhole flow meters; downhole fluid analyzers; and the like.

In the embodiment of FIG. 1, a sampler 22 is located above the packer 18 and a tester valve 24 is located above the packer 18. The downhole tool(s) 20 may be connected to an acoustic modem 25Mi+1 which can be mounted between the sampler 22 and the tester valve 24. The acoustic modem 25Mi+1, operates to allow electrical signals from the downhole tool(s) 20 to be converted into acoustic signals for transmission to the surface via the tubing 14, and to convert acoustic tool control signals from the surface into electrical signals for operating the downhole tool(s) 20. The term “data,” as used herein, is meant to encompass control signals, tool status, and any variation thereof whether transmitted via digital or analog signals.

In order to support acoustic signal transmission along the tubing 14 between the downhole location and the surface, a series of the acoustic modems 25Mi−1 and 25M, etc. may be positioned along the tubing 14. The acoustic modem 25M, for example, operates to receive an acoustic signal generated in the tubing 14 by the acoustic modem 25Mi−1 and to amplify and retransmit the signal for further propagation along the tubing 14. The number and spacing of the acoustic modems 25Mi−1 and 25M will depend on the particular installation selected, for example on the distance that the signal must travel. A typical spacing between the acoustic modems 25Mi−1, 25M, and 25Mi+1 is around 1,000 ft, but may be much more or much less in order to accommodate all possible testing tool configurations. Thus an acoustic signal can be passed between the surface and the downhole location in a series of short hops.

The role of a repeater is to detect an incoming signal, to decode it, to interpret it and to subsequently rebroadcast it if required. In some implementations, the repeater does not decode the signal but merely amplifies the signal (and the noise). In this case the repeater is acting as a simple signal booster. However, this is not the preferred implementation selected for wireless telemetry systems of the present invention.

The acoustic modems 25M, 25Mi−1, and 25Mi+1 will either listen continuously for any incoming signal or may listen from time to time.

The acoustic wireless signals, conveying commands or messages, propagate in the transmission medium (the tubing 14) in an omni-directional fashion, that is to say up and down. It is not necessary for the acoustic modem 25Mi+1 to know whether the acoustic signal is coming from the acoustic modem 25M above or an acoustic modem 25Mi+2 (not shown) below. The direction of the acoustic message is preferably embedded in the acoustic message itself. Each acoustic message contains several network addresses: the address of the acoustic modem 25Mi−1, 25M or 25Mi+1 originating the acoustic message and the address of the acoustic modem 25Mi−1, 25M or 25Mi+1 that is the destination. Based on the addresses embedded in the acoustic messages, the acoustic modem 25Mi−1 or 25M functioning as a repeater will interpret the acoustic message and construct a new message with updated information regarding the acoustic modem 25Mi−1, 25M or 25Mi+1 that originated the acoustic message and the destination addresses. Acoustic messages will be transmitted from acoustic modem 25Mi−1 to 25M and may be slightly modified to include new network addresses.

The acoustic modem 25Mi−2 is provided at surface, such as at or near the well-head equipment 16 which provides a connection between the tubing 14 and a data cable or wireless connection 28 to a control system 30 that can receive data from the downhole tool(s) 20 and provide control signals for its operation.

In the embodiment of FIG. 1, the acoustic telemetry system is used to provide communication between the surface and a section of the tubing 14 located downhole and the downhole tool(s) 20 located in or on the tubing. Although the system is described as including the acoustic telemetry system, it should be understood that other types of telemetry systems, such as mud pulse, and/or electromagnetic telemetry systems can be utilized in accordance with the present disclosure.

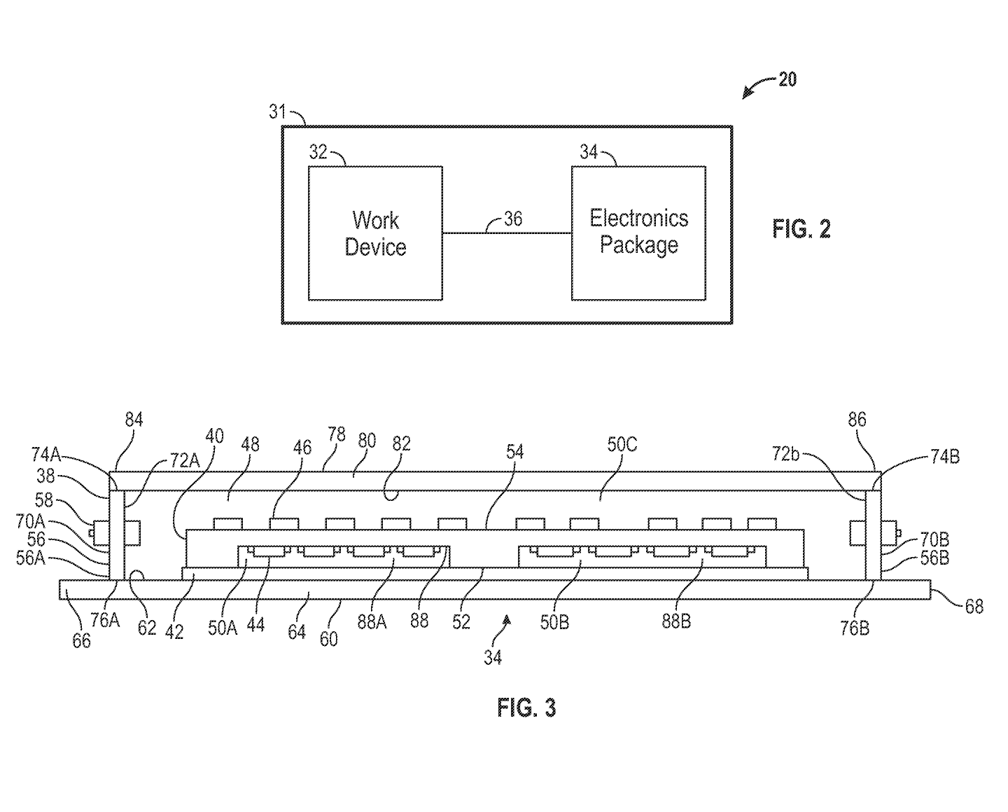

Referring now to FIG. 2, shown therein is a block diagram of an exemplary downhole tool 20. The downhole tool 20 may include a housing 31, one or more work devices 32, and one or more electronics packaging 34. The downhole tool 20 may be secured to the drill string, or generally the tubing 14. The housing 31 of the downhole tool 20 may be composed of any suitable liquid impermeable material known in the art, for example metal, plastic, ceramic, or other composite. The housing 31 may additionally be composed of any suitable liquid impermeable non-corrosive or inert material, such as stainless steel or plastic, in order to better resist temperature, pressure, and other deleterious reactions related to the downhole environment. The work device 32 may be any device that performs the work associated with the downhole tool 20. Exemplary work devices 32 may include actuators, perforators, piezoelectric actuators, solenoids, magnetic field detectors, samplers, pressure gauges, downhole flow meters, downhole fluid analyzers, or any other device associated with downhole tools known in the art. The work device 32 may produce data corresponding to specific measurements, such as magnetic field strength wave forms, pressure, temperature, and the like. The work device 32 may also perform functions such as firing a perforator, initiating an actuator, or any other function associated with downhole tools known in the art. The work device 32 may be electrically connected to the electronics package 34 via a link 36 comprising one or more electrical conductors that may form a bus. The work device 32 may also communicate and receive communications across the link 36 with the electronics packaging 34. For instance the work device 32 may receive instructions from the electronics packaging 34 or may relay instructions or data to the electronics packaging 34 via link 36 for storage, transmission, or processing within the downhole tool 20.

Referring now to FIG. 3, shown therein is an exemplary electronics packaging 34 that can be configured as a multi-chip module (MCM) using one or more dies known to work at high temperatures. The electronics packaging 34 may be provided with a housing 38, one or more substrate 40, one or more seal 42, one or more first type component 44, and one or more second type component 46. The exemplary electronics packaging 34 may be used as a MCM when the one or more first type component 44 and the one or more second type component 46 may be mounted to one substrate 40 such that the one or more first type component 44 and the one or more second type component 46 may act as a single integrated circuit or component. The housing 38 may be composed of any suitable liquid impermeable material known in the art, for example metal, plastic, ceramic, or other composite. For example, the housing 38 may be composed of a non-corrosive or inert material, such as stainless steel, in order to better resist temperature, pressure, and other deleterious reactions related to the downhole environment. The housing 38 may define a void 48. The void 48 may be purged of air, filled with inert gas, and sealed against the downhole environment outside of the downhole tool 20. The inert gas may be argon, nitrogen, or any other suitable inert gas which prevents oxidation, including reactions at downhole temperatures and pressures, or other reactions with the components disposed within the void 48. As will be discussed in more detail below, functionally the housing 38, substrate 40, and seal 42 cooperate to form separate atmospheric chambers within the void 48 that can be used to isolate the one or more first type component 44 and the one or more second type component 46 from one another within the housing 38.

As shown in FIG. 3, the substrate 40, seal 42, first type component 44, and second type component 46 may be disposed within the void 48 within the housing 38. The substrate 40 disposed within the void 48 may cooperate with the housing 38 and seal 42 to form at least two cavities 50. In the example depicted in FIG. 3, the substrate 40 cooperates with housing 38 and the seal 42 to form three cavities 50 (which are designated in FIG. 3 by the reference numerals 50A, 50B and 50C by way of example). The at least one cavity 50 may be separately sealed from the void 48, thereby creating separate atmospheres for differing component types so as to reduce any corrosion or deleterious effects between the one or more first type component 44 and the one or more second type component 46. The cavities 50A, 50B and 50C may be purged of air, filled with inert gas, and sealed against the void 48 within the housing 38 and the downhole environment outside of the downhole tool 20. The inert gas which may fill the two or more cavities 50 may be argon, nitrogen, or any other inert gas which may prevent oxidation or other deleterious reactions, including reactions at downhole temperatures and pressures that may exceed 150 degrees centigrade. The substrate 40 may have a first side 52 and a second side 54. One or more of the cavities 50A, 50B and 50C may be disposed on the first side 52 of the substrate 40, and one or more of the cavities 50A, 50B and 50C may be disposed on the second side 54 of the substrate 40. For example, the cavities 50A and 50B are disposed on the first side 52 of the substrate 40, and the cavity 50C is disposed on the second side 54 of the substrate 40.

Disposed within the at least one cavity 50A on the first side 52 of the substrate 40 may be at least one or more of the first type component 44. The first type component 44 may comprise multiple components requiring similar attachment or bonding technologies which may be placed together within the at least one cavity 50. For instance, the first type component 44 may be any one of a number of active components. Active components often rely on a source of energy, often from a DC circuit, and may be able to introduce power into a circuit although such ability is not required. Active components may include, but are not limited to, transistors, tunnel diodes, semiconductor dies, integrated circuits, optoelectrical devices, piezoelectric devices, or any other such component known in the art. Active components may often employ wire bonding connection technologies, such as aluminum wire bonding of a semiconductor die. In the example depicted in FIG. 3, four of the first type component 44 are provided and connected to the substrate 40. The first type component 44 may be sealed within the cavity 50A by the seal 42. In this example, the seal 42 extends between the substrate 40 and the housing 38.

The second type component 46 may be disposed on the second side 54 of the substrate 40 within the cavity 50C defined by the housing 38. The second type component 46 may comprise multiple components requiring similar attachment or bonding technologies which may be placed together within the void 48, but remaining separate from the first type component 44 sealed within the cavity 50A. For instance, the second type component 46 may be any one of a number of passive components. Passive components may be defined as components which cannot introduce net energy into the circuit to which the passive component is connected. Passive components often rely only on the power available from the circuit to which they are connected. Passive components may include, but are not limited to, resistors, capacitors, inductors, transformers, or any other such component known in the art. The second type component 46 is connected to the substrate 40, preferably using a connection technology which is different from the manner in which the first type component 44 is connected to the substrate 40. For example, the second type component 46 may be connected to the substrate 40 using soldering techniques rather than aluminum wire bonding as described above and may be employed in connecting the first type component 44 to the substrate 40. For example, the second type component 46 may be connected to the substrate 40 utilizing techniques for soldering gold plated contacts.

In other words, techniques for connecting the first type component 44 and the second type component 46 to the substrate 40 may comprise differing component elements and differing connection technologies, such as wire bonding or soldering of gold plated contacts. The differing connection technologies often employed with active components, which may act as the first type component 44, and passive components, which may act as the second type component 46, may be a source of adverse physical or chemical reaction. The adverse physical or chemical reactions which may result from close proximity of differing connection technologies may have deleterious effect on the components and the reliability of the electronics package 34 and the downhole tool 20 in which the electronics package 34 is disposed. The first type component 44 and the second type component 46 are preferably sealed within the cavities 50A and 50C to limit the deleterious effect of combining differing connection technologies, creating separate nonreactive atmospheres within the housing 38.

The housing 38 can be provided in a variety of different manners having various shapes and sizes. In the example shown, the housing 38 is shown having a rectangular cross-section and may be provided with at least one wall 56 and at least one connector 58. As shown in the embodiment of FIG. 2, the connector 58 may be electrically connected to the work device 32 via the link 36. As shown in the embodiment in FIG. 3, the housing 38 may also be provided with a floor member 60 and wall members 56A and 56B. The floor member 60 may be provided with a first side 62 and a second side 64 as well as a first end 66 and a second end 68. The wall members 56A and 56B may be provided with an exterior side 70A and 70B and an interior side 72A and 72B, respectively. Additionally, the wall members 56A and 56B may be provided with first ends 74A and 74B and second ends 76A and 76B, respectively. In the embodiment shown in FIG. 3, the first side 62 of the floor member 60 may be attached to the second ends 76A and 76B of the wall members 56A and 56B. The floor member 60 may be attached to the wall members 56A and 56B by brazing, welding, soldering, chemical adhesive, mechanical connection, or any other suitable method known in the art. In another embodiment, the floor member 60 and the wall members 56A and 56B may be formed of one piece of material.

The housing 38, in the embodiment shown in FIG. 3, may also be provided with two connectors 58A and 58B. The connectors 58A and 58B may be mounted within the wall members 56A and 56B and hermetically sealed. The connectors 58A and 58B may extend beyond the exterior side 70A and 70B of the wall members 56A and 56B, and beyond the interior side 72A and 72B of the wall members 56A and 56B. In another embodiment, the connectors 58A and 58B may not extend beyond the exterior side 70A and 70B or the interior side 72A and 72B of the wall members 56A and 56B.

As shown in the embodiment in FIG. 3, the housing 38 may also be provided with a lid 78. In the example shown, the lid 78 is provided with a first side 80 and a second side 82, and a first end 84 and a second end 86. The lid 78 may be sized and shaped such that when the second side 82 is secured to the first ends 74A and 74B of the wall members 56A and 56B, respectively, the lid 78 may cooperate with the housing 38 to form a seal. The second side 82 of the lid 78 may be secured to the first end 74A and 74B of the wall members 56A and 56B by brazing, welding, chemical adhesive, or any other suitable manner known in the art capable of creating a seal. In another embodiment, the lid 78 may be secured by mechanical connection with a seal member (not shown) such that the lid 78, seal member (not shown), and the housing 38 cooperate to define the void 48 and create a removable seal to separate the void 48 and the contents disposed therein from the downhole environment. When the floor member 60, the wall members 56A and 56B, and the lid 78 are secured together, the contents of the void 48 may be hermetically sealed from the downhole environment.

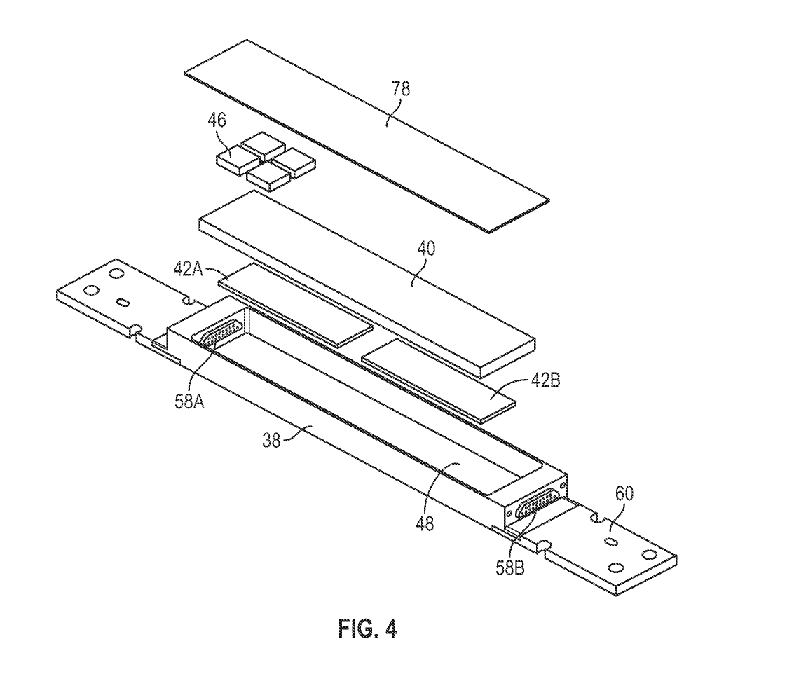

As shown in the embodiment in FIGS. 3 and 4, the substrate 40 provided within the void 48 of the housing 38 may be provided with one or more depression 88 disposed on the first side 52 of the substrate 40 which in part may define at least one cavity 50. As shown in the embodiment in FIG. 3, substrate 40 is provided with two depressions 88A and 88B and the seal 42 spans both depressions 88A and 88B to form the two cavities 50A and 50B. In another embodiment, two separate seals 42 may be provided to form the two cavities 50A and 50B. The seal 42 may be secured to the substrate 40 and the housing 38 by any suitable means to hermetically seal the cavities 50A and 50B, such as by brazing, adhesive, mechanical connection, or any other suitable method known in the art.

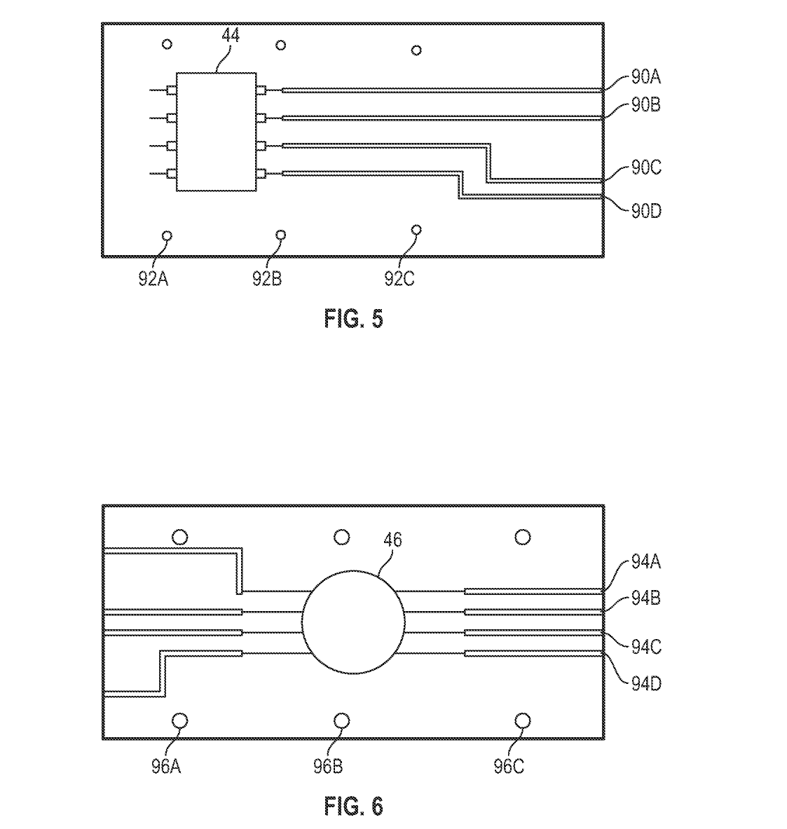

As shown in the embodiments shown in FIGS. 3 and 5, the first type component 44 may be connected to the first side 52 of the substrate 40 through wire bonding technologies. The substrate 40 may also be provided with traces 90A-C and vias 92A-C. Traces 90A-C may be added to the substrate through screen printing, thick film or thin film technology, etching, or any other suitable means known in the art. As shown in FIG. 5, the first type component 44 may be electrically connected to traces 90A-C. In addition, vias 92A-C may be provided for connection between the first side 52 and second side 54 of the substrate 40. Vias 92A-C that travel through the substrate 40 may be solid filled and may form the shortest path through the substrate to carry and spread heat away from the first type component 44.

As shown in the embodiments shown in FIGS. 3, 4, and 6, the second type component 46 may be connected to the second side 54 of the substrate 40 by a soldering technology. The substrate 40 may also be provided with traces 94A-C and vias 96A-C. The traces 94A-C may be added to the second side 54 of the substrate 40 through screen printing, thick film or thin film technology, etching, or any other suitable means known in the art. As shown in FIG. 6, the second type component 46 may be soldered to the traces 94A-C. In addition, vias 96A-C may be provided for connection between the first side 52 and the second side 54 of the substrate 40 so as to form an electrical path through the substrate 40 that may also carry heat away from the second type component 46.

Although only a few embodiments of the present invention have been described in detail above, those of ordinary skill in the art will readily appreciate that many modifications are possible without materially departing from the teachings of the present invention. Accordingly, such modifications are intended to be included within the scope of the present invention as defined in the claims.

What is claimed is:

1. An electronics packaging, comprising:
a housing defining a void;
a substrate positioned within the void of the housing and forming a first cavity and a second cavity relative to the housing, the first cavity and the second cavity being isolated to form separate atmospheric chambers;
at least one first type component disposed in the first cavity and connected to the substrate;
at least one second type component disposed in the second cavity and connected to the substrate, the at least one first type component being different from the at least one second type component.

2. The electronics packaging of claim 1, further comprising a seal positioned between the housing and the substrate to isolate the first cavity from the second cavity.

3. The electronics packaging of claim 1, wherein the at least one first type component is a semiconductor die.

4. The electronics packaging of claim 1, wherein the at least one first type component is connected to the substrate by a first type of connection technology, and wherein the at least one second type component is connected to the substrate by a second type of connection technology with the first and second type of connection technologies being different.

5. The electronics packaging of claim 4, wherein the at least one first type component comprises multiple first type components with all of the first type components connected to the substrate by the first type of connection technology, and wherein the at least one second type component comprises multiple second type components with all of the second type components connected to the substrate by the second type of connection technology.

6. The electronics packaging of claim 4, wherein the first type of connection technology is wire bonding, and the second type of connection technology is soldering.

7. A method of making an electronics packaging, comprising the steps of:
dividing components into a first type and a second type with the first type of component being different from the second type of component;
connecting the first type of component onto a first part of a substrate;
connecting the second type of component onto a second part of a substrate with the first and second parts of the substrate being spaced apart and with the first and second components forming at least part of a circuit;
positioning the substrate into a housing such that the first type of component is isolated from the second type of component; and
sealing the housing.

8. The method of claim 7, wherein the step of connecting the first type of component is defined further as connecting the first type of component to the substrate using a first type of connection technology, and the step of connecting the second type of component is defined further as connecting the second type of component to the substrate using a second type of connection technology with the first and second types of connection technologies being different technologies.

9. The method of claim 7, wherein the first type of component is an active component, and the second type of component is a passive component.

10. A downhole tool, comprising:
a work device;
an electronics packaging connected to the work device; the electronics packaging comprising:
a housing defining a void;
a substrate positioned within the void of the housing and forming a first cavity and a second cavity relative to the housing, the first cavity and the second cavity being isolated to form separate atmospheric chambers;
at least one first type component disposed in the first cavity and connected to the substrate;
at least one second type component disposed in the second cavity and connected to the substrate, the at least one first type component being different from the at least one second type component.

11. The downhole tool of claim 10, further comprising a seal positioned between the housing and the substrate to isolate the first cavity from the second cavity.

12. The downhole tool of claim 10, wherein the at least one first type component is a semiconductor die.

13. The downhole tool of claim 10, wherein the at least one first type component is connected to the substrate by a first type of connection technology, and wherein the at least one second type component is connected to the substrate by a second type of connection technology with the first and second type of connection technologies being different.

14. The downhole tool of claim 13, wherein the at least one first type component comprises multiple first type components with all of the first type components connected to the substrate by the first type of connection technology, and wherein the at least one second type component comprises multiple second type components with all of the second type components connected to the substrate by the second type of connection technology.

15. The downhole tool of claim 13, wherein the first type of connection technology is wire bonding, and the second type of connection technology is soldering.

16. A method of making a downhole tool, comprising the steps of:
dividing components into a first type and a second type with the first type of component being different from the second type of component;
connecting the first type of component onto a first part of a substrate;
connecting the second type of component onto a second part of a substrate with the first and second parts of the substrate being spaced apart and with the first and second components forming at least part of a circuit;
positioning the substrate into a housing such that the first type of component is isolated from the second type of component;
sealing the housing; and
electrically connecting the circuit to a work device.

17. The method of claim 16, wherein the step of connecting the first type of component is defined further as connecting the first type of component to the substrate using a first type of connection technology, and the step of connecting the second type of component is defined further as connecting the second type of component to the substrate using a second type of connection technology with the first and second types of connection technologies being different technologies.

18. The method of claim 16, wherein the first type of component is an active component, and the second type of component is a passive component.
